(19) United States
(12) Patent Application Publication
(10) Pub. No.: US 2024/0103362 A1
(43) Pub. Date: Mar. 28, 2024

(54) METHOD OF PRINTING NANOSTRUCTURE

(71) Applicant: KOREA INSTITUTE OF SCIENCE AND TECHNOLOGY, Seoul (KR)

(72) Inventors: Jong Min KIM, Seoul (KR); Seung Yong LEE, Seoul (KR); So Hye CHO, Seoul (KR); Ho Seong JANG, Seoul (KR); Jae Won CHOI, Seoul (KR); Chang Kyu HWANG, Seoul (KR)

(73) Assignee: KOREA INSTITUTE OF SCIENCE AND TECHNOLOGY, Seoul (KR)

(21) Appl. No.: 18/470,084

(22) Filed: Sep. 19, 2023

(30) Foreign Application Priority Data
Sep. 26, 2022 (KR) 10-2022-0121612

(51) Int. Cl. G03F 7/00; B82Y 30/00; B82Y 40/00

(52) U.S. Cl. CPC G03F 7/0002; B82Y 30/00; B82Y 40/00

(57) ABSTRACT

Disclosed herein is a method of printing a nanostructure including: preparing a template substrate on which a pattern is formed; forming a replica pattern having an inverse phase of the pattern by coating a polymer thin film on an upper portion of the template substrate, adhering a thermal release tape to an upper portion of the polymer thin film, and separating the polymer thin film from the template substrate; forming a nanostructure by depositing a functional material on the replica pattern; and printing the nanostructure deposited on the replica pattern to a substrate by positioning the nanostructure on the substrate, applying heat and pressure to the nanostructure, and weakening an adhesive force between the thermal release tape and the replica pattern by the heat.

### CROSS REFERENCE TO RELATED APPLICATION

The present application claims priority to Korean Patent Application No. 10-2022-0121612, filed Sep. 26, 2022, the entire contents of which is incorporated herein for all purposes by this reference.

### BACKGROUND OF THE INVENTION

### Field of the Invention

The present disclosure relates to a method of printing a nanostructure, and more particularly, to a method of printing a nanostructure that enable easy and large-scale manufacturing of the nanostructure using a low-cost and a simplified process.

### Description about National Research and Development Support

This study was supported by the technology development program of Ministry of Science and ICT, Republic of Korea (Projects No. 1711173294) under the superintendence of National Research Foundation of Korea.

### Description of the Related Art

Currently, there is an increasing demand for easy and uniform ultra-fine nanostructure manufacturing technology in various fields such as semiconductors, electronic devices, biosensors, and catalysts, and the related technology, nanotransfer printing method, requires a high level of interest and technology.

The nanotransfer printing method offers a low-cost and simplified process for easily manufacturing the nanostructures of functional materials. This method demonstrates excellent scalability and hold significant potential as next generation nano-manufacturing technologies with promising future prospects.

The nanotransfer printing method enables easy manufacturing of the nanostructures of functional materials such as metals and semiconductors. This method allows for the arrangement of these nanostructures in two-dimensional or three-dimensional patterns. Particularly, it is possible to form nanostructures on flexible substrates, which are challenging to achieve using an existing patterning techniques.

In addition, if the resolution of these nanotransfer printing technologies can be improved to below 10 nm, it is expected that not only can high-performance electronic devices be manufactured through simple and low-cost processes, but also the quantum effects observed in nanostructures with several nanometers in size can be used, which opens up possibilities for the development of new high-performance nano-devices that surpass conventional electronic devices.

### DOCUMENTS OF RELATED ART

(Patent Document 1) Korean Patent No. 10-1632504
(Patent Document 2) Korean Patent No. 10-2186501

### SUMMARY OF THE INVENTION

Generally, one of the nanotransfer printing methods involves depositing functional materials onto a polymer thin film mold and then printing the functional materials onto a target substrate using organic solvent vapor. However, this method has very complicated processes, and particularly when printing using organic solvent vapor, there is a problem in that the alignment and yield of nanostructures vary depending on the extent of swelling of the polymer thin film by the solvent.

In addition, this method has various limitations, such as delamination in which the layered structures of the target substrate are torn off during the multi-layer print process.

In addition, the method of forming nanostructures by printing the nanostructures to the target substrate using organic solvent vapor is a method in which the organic solvent vapor penetrates between a polymer replica mold and an adhesive film to make an adhesive force weakened and then the nanostructures are printed to the substrate, but in case of flat thin films and patterned thin film materials, there is a limitation that the organic solvent vapor cannot penetrate all the way to the polymer replication mold, thus making it impossible to print. In addition, among other nanotransfer printing methods, the method of manufacturing a film with a replica pattern having the inverse phase of a master pattern and then printing nanostructures to a target substrate using a rolling process and a heat-assisted system enables large-area print, but there is a limitation in that it is very difficult to print the nanostructures to the target substrate in multiple layers due to the adhesive properties of the tape supporting the replica pattern.

For example, the method described in patent document 1 is to print a nanostructure by depositing a functional material on a PMMA replica mold and then allowing organic solvent vapor to penetrate between the PMMA replica mold and an adhesive film, thereby reducing an adhesive force between the PMMA replica mold and the adhesive film.

However, the entire process in patent document 1 is very complicated, and since the print is performed using organic solvent vapor, there is a problem in that reliability of the print yield depends on how much the organic solvent penetrates between the PMMA replica mold and the adhesive film.

In addition, in case of manufacturing nanostructures that are stacked in multiple layers through a multilayer printing process, if there is an area where the organic solvent is not sufficiently exposed during the printing process, there is a problem in that the delamination phenomenon occurs that some of the printed nanostructure thin films may peel off due to the adhesiveness of the adhesive film.

Meanwhile, the method described in patent document 2 is a method of manufacturing a film in which a replica pattern having an inverse phase of a master pattern is formed, and then print the film to a target substrate using a heat assisted system.

However, in the process of printing a single layer, patent document 2 has the inconvenience of performing a roll-to-roll process multiple times, and patent document 2 also has difficulty printing nanostructures in multiple layers because the delamination phenomenon occurs due to the strong adhesion of the adhesive film.

Therefore, there is a demand for nanotransfer printing methods that are easy, cost-effective, capable of large area manufacturing, and enable easy multilayer formation.

In order to achieve the above-described technical objects, the present disclosure is directed to providing a method of printing a nanostructure including: preparing a template substrate on which a pattern is formed; forming a replica pattern having an inverse phase of the pattern by coating a polymer thin film on an upper portion of the template substrate, adhering a thermal release tape to an upper portion of the polymer thin film, and separating the polymer thin film from the template substrate; forming a nanostructure by depositing a functional material on the replica pattern; and printing the nanostructure deposited on the replica pattern to a substrate by positioning the nanostructure on the substrate, applying heat and pressure to the nanostructure, and weakening an adhesive force between the thermal release tape and the replica pattern by the heat.

In addition, the template substrate may have a surface pattern in the form of a concave-convex by forming a pattern of a desired size using one or more patterning processes selected from a group consisting of photolithography, block copolymer self-assembly-based lithography, nanoimprint lithography, and E-beam lithography, and proceeding to a surface etching with a reactive ion etching (RIE) process.

In addition, the method according to the present disclosure may proceed with the replica pattern remaining adhered to the thermal release tape by uniformly adhering the thermal release tape to one surface of the polymer thin film and peeling off the polymer thin film from the template substrate.

In addition, in the present disclosure, the adhering of the thermal release tape uniformly to one surface of the polymer thin film may be carried out through a rolling process or a pressing process.

In addition, the thermal release tape of the present disclosure may include a thermal release adhesive layer disposed between two films.

In addition, in the present disclosure, the forming a nanostructure by depositing a functional material is carried out by tilting the replica pattern so that a surface of the replica pattern on which the deposition is carried out and a direction of the deposition form a predetermined angle and depositing the functional material on a surface of the replica pattern, such that the deposition of the functional material is carried out only on a raised portion on the surface of the replica pattern due to a shadow effect.

In addition, the method according to the present disclosure may further include brush coating the upper portion of the template substrate with a polydimethylsiloxane (PDMS) polymer prior to coating the polymer thin film on the upper portion of the template substrate.

In addition, the coating of the polymer thin film on the upper portion of the template substrate of the present disclosure may be carried out by a spin coating.

In addition, the functional material of the present disclosure may be one or more species selected from Au, Pt, Ni, Co, Pd, Ag, SiO₂, and oxides thereof.

In addition, the positioning of the nanostructure deposited on the replica pattern of the present disclosure on the target substrate and applying heat and pressure to the nanostructure is carried out at a temperature range of 110 to 150° C.

In addition, the positioning of the nanostructure deposited on the replica pattern of the present disclosure on the target substrate and applying heat and pressure to the nanostructure is carried out for 10 to 60 seconds.

In addition, in the present disclosure, after the nanostructure is printed onto the substrate, the replication pattern is washed with an organic solvent so that the polymer thin film is removed and the nanostructure may be printed onto the substrate.

### BRIEF DESCRIPTION OF THE DRAWINGS

FIG. 1 is a photographic view briefly illustrating an entire process of a method of printing a nanostructure according to an embodiment of the present disclosure.

FIG. 2 is a schematic view illustrating the method of printing a nanostructure according to an embodiment of the present disclosure.

FIG. 3 is a graph schematically illustrating a structure and characteristics of a thermal release tape according to an embodiment of the present disclosure.

FIG. 4 is SEM images in which Au patterns are formed as a monolayer on a silicon substrate according to an embodiment of the present disclosure.

FIG. 5 is SEM images in which Au patterns are formed as a plurality of layers on a silicon substrate according to an embodiment of the present disclosure.

FIG. 6 is SEM images in which LaSrCoO oxide patterns are formed in a plurality of layers on a silicon substrate according to an embodiment of the present disclosure.

FIG. 7 is SEM, TEM, and TEM EDS mapping images after CeGdO oxide and Ni structures are simultaneously printed onto a silicon substrate as a monolayer structure according to an embodiment of the present disclosure.

### DETAILED DESCRIPTION OF THE INVENTION

Hereinafter, a method of printing a nanostructure according to a preferred embodiment of the present disclosure will be described with reference to the accompanying drawings.

Prior to the description, unless explicitly described to the contrary, the word “comprise” or “include” and variations, such as “comprises”, “comprising”, “includes” or “including”, will be understood to imply the inclusion of stated constituent elements, not the exclusion of any other constituent elements.

In addition, in the various embodiments, the constituent elements having the same constitution will be described using the same reference numerals, typically in an embodiment, and only different constituent elements will be described in other embodiments.

Further, while the embodiments of the present disclosure have been described with reference to the accompanying drawings, they are described for illustrative purposes only and are not intended to limit the technical spirit of the present disclosure and the constitution and application thereof.

As described above, the present disclosure relates to a method of printing a nanostructure, and more particularly, to a method of printing a nanostructure that enable easy and large-scale manufacturing of the nanostructure using a low-cost and a simplified process.

To this end, in the present disclosure, a polymer thin film is coated on an upper portion of a template substrate, a thermal release tape is adhered to the upper portion of the polymer thin film to separate the polymer thin film from the template substrate to form a replica pattern having an inverse phase of the pattern, a functional material is deposited on the replica pattern to form a nanostructure, the nanostructure deposited on the replica pattern is positioned on a target substrate, heat and pressure are applied to the target substrate, and an adhesive force between the thermal release tape and the replica pattern is weakened by heat so that the nanostructure can be printed to the target substrate.

Therefore, in the present disclosure, heat and pressure are used to manufacture three-dimensional nanostructures very easily, and printing structures of various materials such as metals and ceramics are possible in an easy process method. In addition, various three-dimensional structures with large areas such as thin films as well as patterned nanowire structures can be manufactured through a control of various process variables.

More specifically, the present disclosure will be described with reference to specific embodiments below.

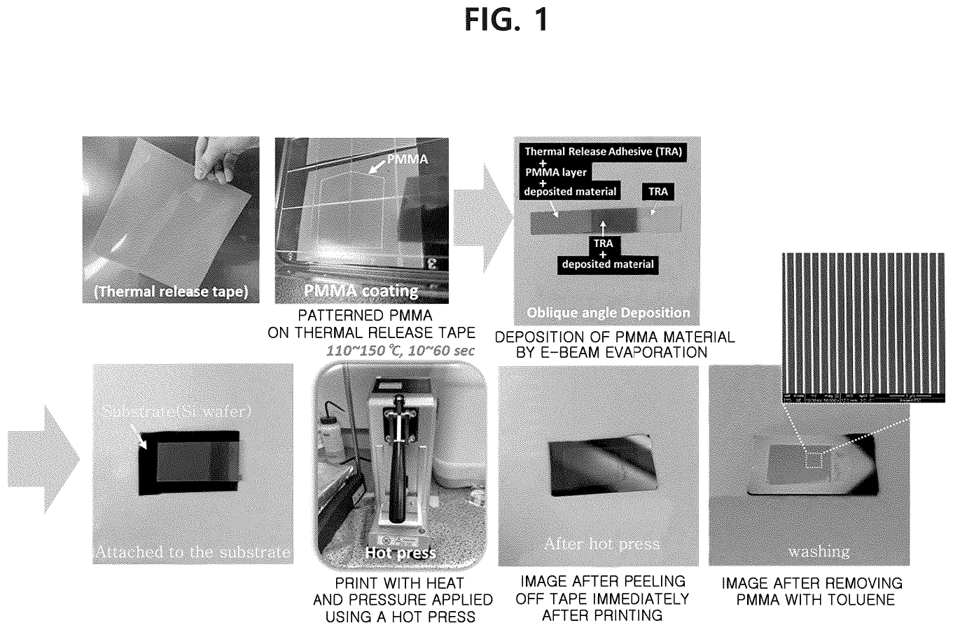

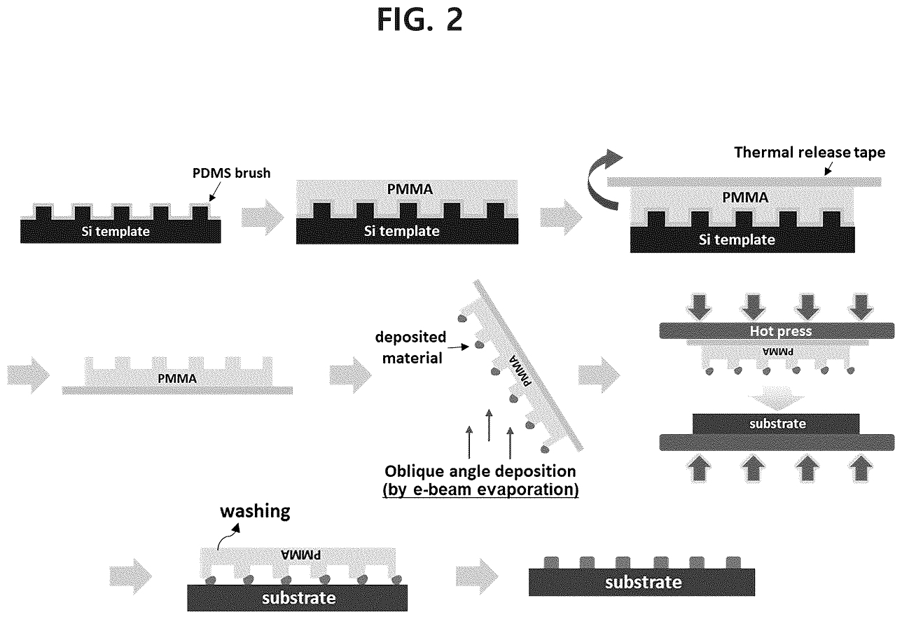

FIG. 1 is a photographic view briefly illustrating an entire process of a method of printing a nanostructure according to an embodiment of the present disclosure, and FIG. 2 is a schematic view illustrating the method of printing a nanostructure according to an embodiment of the present disclosure.

As illustrated in FIGS. 1 and 2, a method of printing a nanostructure according to an embodiment of the present disclosure includes manufacturing a template substrate using lithography technology, coating a polymer thin film and peeling off a replica pattern using a thermal release tape, depositing a functional material to form a functional nanostructure, applying heat and pressure to weaken an adhesive force between the polymer thin film and the adhesive tape, and printing the nanostructure onto various target substrates.

Specifically, a patterning process such as photolithography, block copolymer self-assembly-based lithography, or E-beam lithography is used to form a pattern of a desired size on a substrate such as a silicon wafer, and a template substrate (a master substrate) having a surface pattern in the form of a concave-convex is manufactured by surface etching with a reactive ion etching (RIE) process.

Next, the template substrate is coated, for example, with a polydimethylsiloxane (PDMS) polymer brush coating with a low surface energy of 30 mJ/m² or less. This allows the replica pattern mold to be easily removed from the template substrate in subsequent processes.

Next, a thin film of PMMA polymer is applied to the template substrate using methods such as spin coating to form a thin film. In this embodiment, the polymer thin film was applied using spin coating, but methods such as deep coating and spray coating are also possible.

The applied polymer thin film may have a solubility parameter of 20 to 40 MPa^{1/2}, and the glass transition temperature of the polymer is higher than room temperature, so that the polymer can maintain a stable solid state at room temperature.

Next, a thermal release tape is adhered to the formed PMMA polymer thin film and then peeled off again, so that a nano-replica patterned thin film mold may be formed.

Specifically, when the thermal release tape is adhered to the PMMA polymer thin film, the adhesive film can be uniformly adhered to the polymer thin film over a large area, and the adhesive force between the replica pattern and the adhesive film can be improved because the adhesion is carried out by a rolling process or a pressing process.

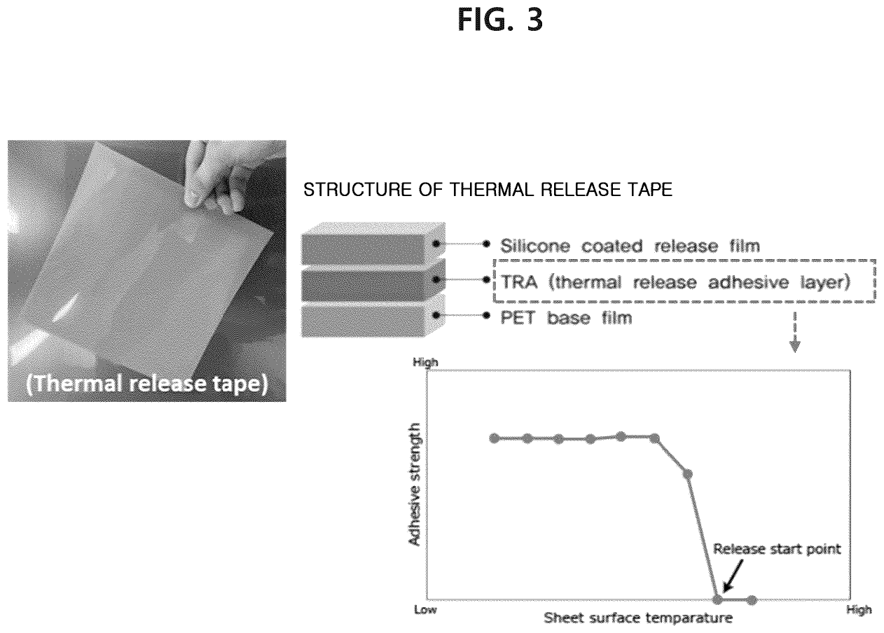

FIG. 3 is a graph schematically illustrating a structure and characteristics of a thermal release tape according to an embodiment of the present disclosure.

As illustrated in FIG. 3, the thermal release tape according to an embodiment of the present disclosure is a structure in which a thermal release adhesive layer is disposed between two films, and the adhesive force is lost when the temperature exceeds a predetermined range. In an embodiment of the present disclosure, the thermal release tape loses the adhesive force in case that the temperature exceeds 110° C., and subsequently, when heat is applied in the temperature range of 110 to 150° C. during a print step, the adhesive force is weakened so that the thermal release tape can be easily separated from the PMMA replica pattern mold.

Therefore, in the present disclosure, the nanostructure can be stably printed to the target substrate because the adhesive tape can be separated by heat only.

Next, using an E-beam evaporation deposition technique (thermal evaporation, sputter, etc.) on the replica pattern mold, the material is deposited at an inclined angle to the mold to ensure that the material is deposited only on a raised portion of the surface of the mold.

The functional material that is deposited may be one or more species selected from Au, Pt, Ni, Co, Pd, Ag, SiO₂, and oxides thereof, which have relatively low resistance to organic solvents.

Next, the replica patterned thin film with the functional material deposited is placed on the target substrate to be printed and subjected to heat and pressure. In an embodiment of the present disclosure, a hot press was used to apply pressure with heat of 110 to 150° C. for 10 to 60 seconds. As described above, since the thermal release tape, which is an adhesive film, is subjected to heat above the temperature at which the thermal release tape loses the adhesive force, the thermal release tape that has lost the adhesive force is easily removed, and only the PMMA polymer replica pattern with the functional material deposited is present on the substrate to be printed.

Next, since the PMMA polymer replica pattern remains on the target substrate after the print process, the residual replica pattern material can be removed by washing with an organic solvent such as toluene, or water, or the like, thereby forming a three-dimensional nanostructure on the target substrate.

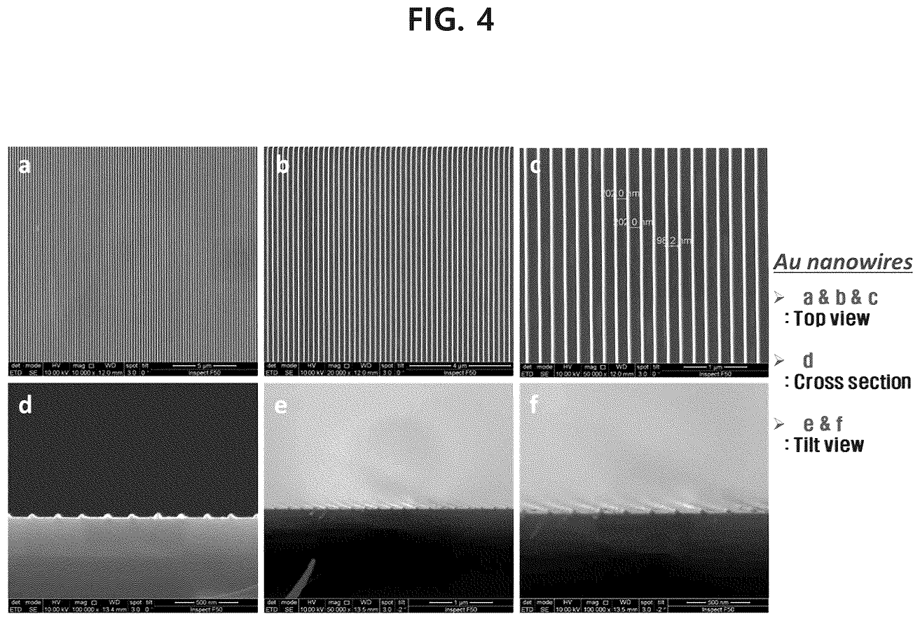

FIG. 4 is SEM images in which Au patterns are formed as a monolayer on a silicon substrate according to an embodiment of the present disclosure. As illustrated in FIG. 4, it can be seen that the print of the three-dimensional nanowire structure pattern with high uniformity has been successfully achieved.

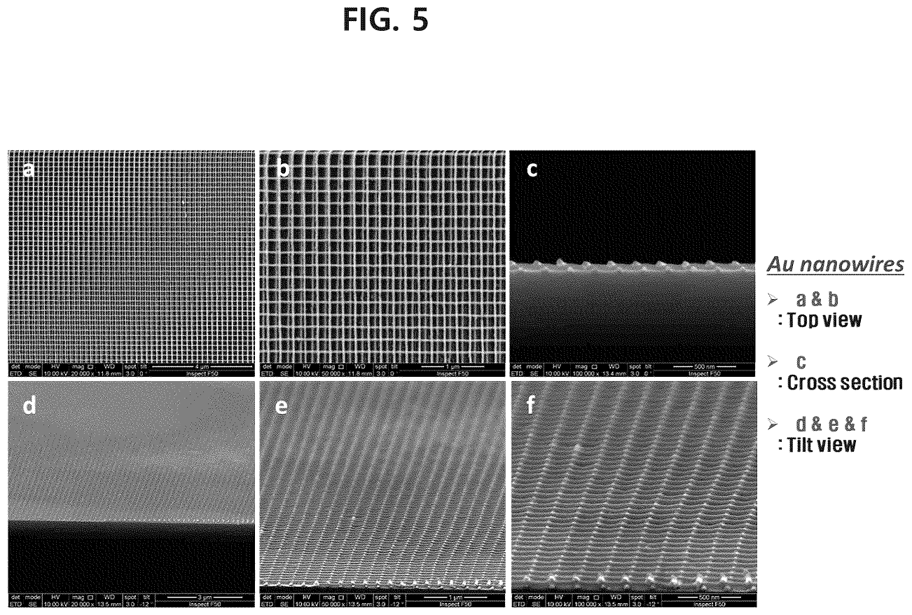

FIG. 5 is SEM images in which Au patterns are formed as a plurality of layers on a silicon substrate according to an embodiment of the present disclosure. As illustrated in FIG. 5, it is possible to manufacture not only monolayer but also three-dimensional nanowire structure patterns as a plurality of layers on a silicon wafer, and it can be seen that these multilayer structures also exhibit high uniformity.

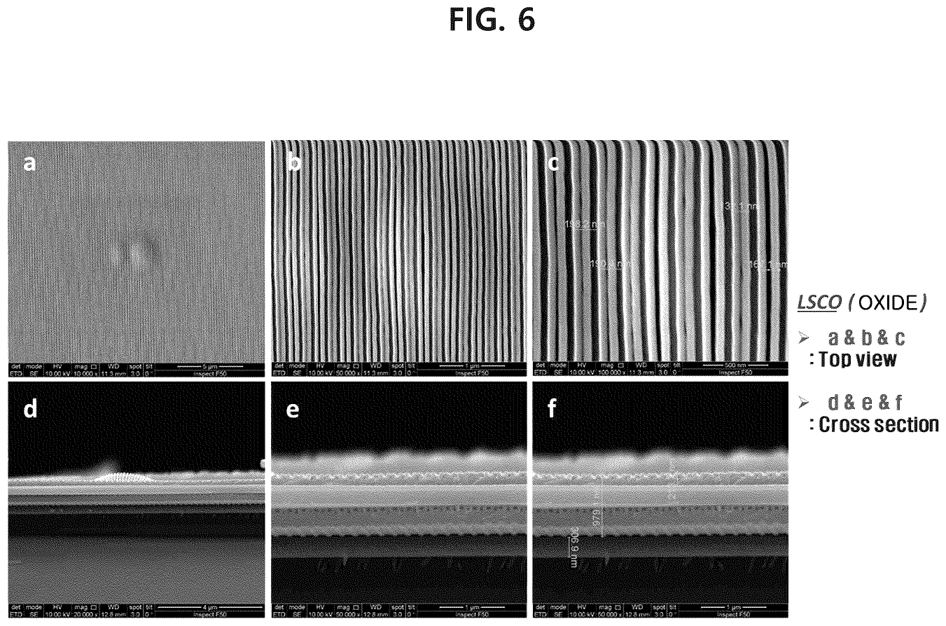

FIG. 6 is SEM images in which LaSrCoO oxide patterns are formed in a plurality of layers on a silicon substrate according to an embodiment of the present disclosure.

As illustrated in FIG. 6, a LSCO (lanthanum (La) strontium (Sr) cobalt (Co) oxide (O)) oxide patterned thin film printed in a plurality of layers structure on a wafer has been formed, and it can be seen that not only metallic materials but also various oxides including LSCO can be easily manufactured using an embodiment of the present disclosure. In addition, it can be seen that in addition to the print of patterns with nanowire structures, structures in the form of a thin film with patterns can also be printed to the substrate.

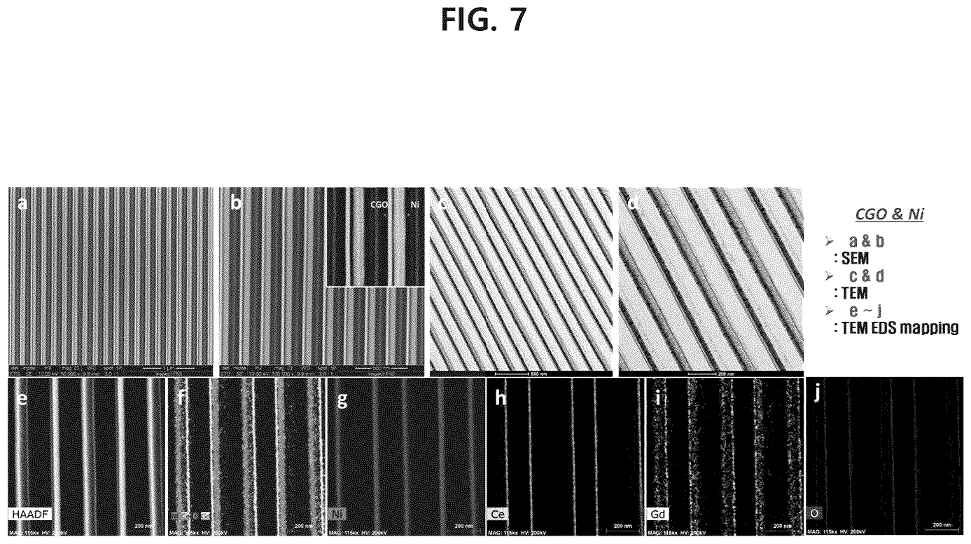

FIG. 7 is SEM, TEM, and TEM EDS MAPPING images after CeGdO oxide and Ni structures are simultaneously printed onto a silicon substrate as a monolayer structure according to an embodiment of the present disclosure.

As illustrated in FIG. 7, cerium gadolinium oxide (CeGdO) and Ni structures have been simultaneously printed to a silicon wafer in a monolayer structure, and it can be seen that two or more materials can be deposited on the patterned PMMA by controlling a vacuum process in which functional materials are deposited, which can then be printed to the substrate using the thermal release tape. Therefore, it can be seen that Ni and CeGdO have formed a nanowire structure with good print performance, and that Ni and CeGdO have formed into a nanostructure with a certain periodicity while having respective elemental composition through TEM EDS mapping.

With reference to the aforementioned description, those skilled in the art to which the present disclosure belongs will understand that the present disclosure may be carried out in other specific forms without changing the technical spirit or essential characteristics of the present disclosure.

Accordingly, it is to be understood that the embodiments described above are illustrative in all respects and are not intended to limit the present disclosure to the embodiments, and the scope of the present disclosure is indicated by the patent claims which are hereinafter recited rather than by the foregoing detailed description, and the meaning and scope of the patent claims and all modifications or variations derived from the equivalent concepts should be interpreted to be included within the scope of the present disclosure.

What is claimed is:

1. A method of printing a nanostructure comprising:
preparing a template substrate on which a pattern is formed;
forming a replica pattern having an inverse phase of the pattern by coating a polymer thin film on an upper portion of the template substrate, adhering a thermal release tape to an upper portion of the polymer thin film, and separating the polymer thin film from the template substrate;
forming a nanostructure by depositing a functional material on the replica pattern; and
printing the nanostructure deposited on the replica pattern to a substrate by positioning the nanostructure on the substrate, applying heat and pressure to the nanostructure, and weakening an adhesive force between the thermal release tape and the replica pattern by the heat.

2. The method of claim 1, wherein the template substrate has a surface pattern in the form of a concave-convex by forming a pattern of a desired size using one or more patterning processes selected from a group consisting of photolithography, block copolymer self-assembly-based lithography, nanoimprint lithography, and E-beam lithography, and proceeding to a surface etching with a reactive ion etching (RIE) process.

3. The method of claim 1, wherein the method proceeds with the replica pattern remaining adhered to the thermal release tape by uniformly adhering the thermal release tape to one surface of the polymer thin film and peeling off the polymer thin film from the template substrate.

4. The method of claim 3, wherein the thermal release tape comprises a thermal release adhesive layer disposed between two films.

5. The method of claim 3, wherein the adhering of the thermal release tape uniformly to one surface of the polymer thin film is carried out through a rolling process or a pressing process.

6. The method of claim 1, wherein the forming a nanostructure by depositing a functional material is carried out by tilting the replica pattern so that a surface of the replica pattern on which the deposition is carried out and a direction of the deposition form a predetermined angle and depositing the functional material on a surface of the replica pattern, such that the deposition of the functional material is carried out only on a raised portion on the surface of the replica pattern.

7. The method of claim 1, further comprising:
brush coating the upper portion of the template substrate with a polydimethylsiloxane (PDMS) polymer prior to coating the polymer thin film on the upper portion of the template substrate.

8. The method of claim 1, wherein the coating of the polymer thin film on the upper portion of the template substrate is carried out by a spin coating.

9. The method of claim 1, wherein the functional material is one or more species selected from Au, Pt, Ni, Co, Pd, Ag, Si, and oxides thereof.

10. The method of claim 1, wherein the positioning of the nanostructure deposited on the replica pattern on the substrate and applying heat and pressure to the nanostructure is carried out at a temperature range of 110 to 150° C.

11. The method of claim 1, wherein the positioning of the nanostructure deposited on the replica pattern on the substrate and applying heat and pressure to the nanostructure is carried out for 10 to 60 seconds.

12. The method of claim 1, wherein after the nanostructure is printed onto the substrate, the replication pattern is washed with an organic solvent so that the polymer thin film is removed and the nanostructure is printed onto the substrate.
